(19) United States
(12) Patent Application Publication
(10) Pub. No.: US 2010/0288689 A1
(43) Pub. Date: Nov. 18, 2010

(54) MICROFLUIDIC FILTRATION UNIT, DEVICE AND METHODS THEREOF

(75) Inventors: Liang Zhu, Singapore (SG); Wen-Tso Liu, Singapore (SG); Hanhua Feng, Singapore (SG); Hong Miao Ji, Singapore (SG); William Cheng Yong Teo, Singapore (SG); Ramana Murthy Badam, Singapore (SG)

Correspondence Address: CONNOLLY BOVE LODGE & HUTZ LLP, 1875 EYE STREET, N.W., SUITE 1100, WASHINGTON, DC, 20006, US

(73) Assignee: AGENCY FOR SCIENCE, TECHNOLOGY AND RESEARCH, Connexos (SG)

(21) Appl. No.: 12/438,505

(22) PCT Filed: Aug. 22, 2006
(86) PCT No.: PCT/SG2006/000242

§ 371 Date: Jul. 30, 2010

(51) Int. Cl. B81B 1/00; B01D 29/03; B01D 29/50

(52) U.S. Cl. 210/336; 210/335

(57) ABSTRACT

A microfluidic filtration unit for trapping particles of a predetermined nominal size present in a fluid is provided. The unit comprises a fluid chamber connected to an inlet for introducing the fluid to be filtered and an outlet for discharging filtered fluid, a filtration barrier arranged within the fluid chamber, said filtration barrier comprising a plurality of pillars arranged substantially perpendicular to the path of fluid flow when fluid is introduced into the fluid chamber, said pillars being aligned to form at least one row extending across said path of fluid flow, wherein each of said at least one row of pillars in the filtration barrier comprises at least one fine filtration section comprising a group of pillars that are spaced apart to prevent particles to be filtered from the fluid from moving between adjacent pillars, and at least one coarse filtration section comprising a group of pillars that are spaced apart to permit the movement of particles between adjacent pillars.

The present invention relates to the field of microfluidics, and more particularly to microfluidic filtration units.

### BACKGROUND OF THE INVENTION

In recent years, microfluidic filtration devices, more commonly known as microfilters, have come to play an important role in lab-on-a-chip biomolecular analytical systems in which they are required for the separation of particles with micro- and nano-scale sizes from small volumes of liquid of several hundred microlitres, typically biological samples containing microscopic cellular particles.

Various types of microfilters have been developed and can be broadly categorised as either active or passive microfilters. Examples of active microfilters include ultrasonic microfilters, magnetic microfilters, and dielectrophoresis microfilters. Passive microfilters include various sieve-type microfilters. While active microfilters are capable of filtering particles present in low concentrations in a sample, conventional passive microfilters are simpler in design and thus cheaper to fabricate. For this reason, efforts have been continually directed towards the development of passive type microfilters, especially for disposable microfluidic devices that are used in applications meant for consumer segments of the market.

Passive microfilters typically comprise a horizontal screen structure arranged within a channel through which the sample flows to prevent the movement of oversized particles. One class of passive microfilters comprise a membrane for trapping particles. WO 2004/074169 and U.S. Pat. No. 6,811,695 describe microfilters having porous polymer membranes as the filter element. Polymeric membranes are generally less effective for mechanical filtration. Due to the statistical pore size distribution inherent to current fabrication techniques of polymer membranes, small and large pores are randomly formed in any given sample of the membrane filter, and particles to be captured are inevitably lost through these large pores, resulting in low trapping efficiencies.

Another type of passive microfilter is known as the H-filter, developed by Brody and Yager. The H-filter relies on the diffusive mixing between adjacent laminar streams in order to passively separate small particles from a sample which contains both small and large particles. By controlling the input stream flow rates of the adjacent laminar streams and the geometry of the channel through which the laminar streams flow, the time allowed for diffusion of particles can be restricted such that only small particles are given sufficient time to diffuse to the adjacent stream, thereby isolating them from the larger particles. For example, small particles like haemoglobin in water normally takes about 300 hours to diffuse 1 cm, but only around 1 second to diffuse 10 microns. However, larger particles, such as red blood cells, need about 10 minutes to diffuse 10 microns. The smaller haemoglobin particles will readily move across the flow stream to the filter output and can therefore be separated from the larger red blood cells.

More recently, pillar-type passive microfilters derived from silicon have been disclosed by Wilding et al (Wilding, P.; Kricka, L. J.; Cheng, J.; Hvichia, G.; Shoffner, M. A.; Fortina, P. Anal. Biochem. 1998, 257, 95-100), and comprise a pillar-type screening structure placed across the path through which fluid is required to flow. Pillar-type microfilters often suffer from high flow resistance and high sensitivity to clogging. High sensitivity to clogging means that the filter will cease to function after a relatively short period of time, as most of its available pores/opening are filled up and blocked. After a period of use, the accumulation of particles at the filter gaps will result and this gives rise to high flow resistance. High flow resistance in turn creates high hydrodynamic pressure at the filters. This not only creates difficulties in the injection of the sample into the device, but may bring about the breakage of the microfiltration unit. Furthermore, cell membranes of ‘captured’ cells may be damaged by the high pressure and thus rendered useless for analysis. In view of these problems, attempts have been made to improve the construction of microfilters in order to reduce their clogging tendency.

U.S. Pat. No. 5,922,210 discloses microfilters utilizing principles of tangential flow to prevent clogging. A row of pillars constituting the microfilters in the device are arranged parallel to the path of fluid to be filtered. On the other side of the microfilter, filtrate is collected in a collection chamber. When used for purification, only several nanoliters of purified fluid can be obtained from a 1 μl sample.

WO 01/85341 discloses a microfluidic device for trapping particles. Rectangular pillar elements are arranged to form a square filter cage located within a fluid chamber. Fluid introduced into the device is directed into the cage so that particles to be filtered from the fluid is trapped and concentrated within the cage.

A microfilter fabricated in quartz consisting of a network of intersecting micro-channels is disclosed by He et al. (Anal. Chem. 1999, 71, 1464-1468). When placed at the bottom of reservoirs with a side-exit, the channel network behaved as a lateral percolation filter comprising an array of cube-like structures arranged in a single layer.

Kim et al. (Lab Chip, 2006, 6, 794-802) discloses an integrated microfluidic device for blood typing. The device comprises trapezoidal shaped micropillars having gradually decreasing filter gap sizes ranging from 200 μm to 50 μm in the downchannel direction for filtering agglutinated red blood cells. The concept behind this configuration is to filter out particles stage by stage, starting from the coarser particles and finishing with the finer particles.

In all the above pillar-type microfiltration units, one frequently encountered problem is that the upstream filters are clogged after a short period of use, and fluid is eventually unable to flow through the filter, thereby leading to high pressure and potential breakage. This situation is especially common if the volume of sample fluid to be processed is relatively large and contains a large quantity of particles. Unless it is carefully monitored over the course of filtration, the parts of the microfiltration unit tends to be mechanically weakened or even break from the spike in hydrodynamic pressure, leading to leaks and loss of filtered particles and filtrate.

In view of the prevalent problems in existing microfilters, an object of the present invention is to provide a microfluidic filtration unit which overcomes some of the drawbacks of the prior art devices, for example by providing microfluidic filters that suffer from less clogging problems, with minimal compromise in trapping efficiency.

### SUMMARY OF THE INVENTION

According to a first aspect of the present invention, a microfluidic filtration unit for trapping particles of a predetermined nominal size present in a fluid is provided, comprising a fluid chamber connected to an inlet for introducing the fluid to be filtered and an outlet for discharging filtered fluid, a filtration barrier arranged within the fluid chamber, said filtration barrier comprising a plurality of pillars arranged substantially perpendicular to the path of fluid flow when fluid is introduced into the fluid chamber, said pillars being aligned to form at least one row extending across said path of fluid flow. Each of the at least one row of pillars in the filtration barrier comprises at least one fine filtration section comprising a group of pillars that are spaced apart to prevent particles to be filtered from the fluid from moving between pillars, and at least one coarse filtration section comprising a group of pillars that are spaced apart to permit the movement of particles between adjacent pillars.

In another aspect, the invention is directed to a method of purifying a fluid containing particles having a predetermined nominal size or range of sizes. A further aspect of the invention is directed to a method of extracting particles of a predetermined nominal size or range of sizes from a fluid.

The microfilter according to the present invention advantageously provides a filtration barrier comprising pillars arranged such that they define one or more sections of fine filters as well as one or more sections of coarse filters arranged alongside each other within each row of pillars. Coarse filters (hereinafter also known as “by-pass filters”) are designed such that large particles are able to pass between the pillars forming the coarse filters. By placing coarse filters alongside fine filters, fine filters function to trap targeted particles while potential clog factors which can block the fine filters are allowed to by-pass the fine filters via the coarse filters, thereby preventing clogging up the fine filters. In other words, the coarse filters act as an anti-clogging facility wherein large particles are vented out of the microfilter. An advantage of this construction is that it allows a significantly larger quantity of fluid to be processed before clogging starts to set in. It also extends the lifespan of the microfilter by reducing the possibility of breakage resulting from pressure build-up due to clogging. Although small targeted particles may escape through the coarse filters of the filtration barrier, particle loss can be minimised by various means. For example, the overall number of fine filters can be increase by implementing a larger number of rows of filters, thereby enabling escaped particles to be recovered in downstream sections of the filtration barrier. The extent of particle loss can also be reduced by optimising the proportion of fine filtration sections and coarse filtration sections within each row of filters, as well as the porosity/size of filter gaps in the coarse filtration section. Thus, by implementing both by-pass filters and fine filters in the filtration barrier, the microfiltration unit of the invention helps to prevent the build up of flow resistance due to the accumulation of micro-particles at the filter, while still maintaining a relatively high trapping efficiency.

The present invention is applicable to any type of fluids, including pure liquids, solutions, mixtures, as well as fluids containing particles such as suspensions, colloidal systems, colloidal solutions, or colloidal dispersions. Examples of fluids which may be processed by the microfiltration unit according to the invention includes water samples, liquid food, biological fluids such as saliva, blood, urine, semen, etc.

The microfiltration unit of the invention may be used to filter any type of particles that are present in a fluid. The term ‘particles’ refer to small particles having a size in the range of several hundred micrometers to less than 1 micrometer. In this context, the term ‘particle’ includes both inorganic particles (such as silica micro-spheres, glass beads and magnetic beads) and organic particles. Organic particles include biological materials such as peptides, proteins, DNA, viruses, tissue fragments, plant cells, animal cells and microbial cells. Cells to which the invention can be applied include both eukaryotic cells and prokaryotic cells. Prokaryotic cells applicable in the invention include, for example, archaeal cells and bacterial cells. Some examples of prokaryotic cells include Escherichia coli and Vibrio cholera. Examples of eukaryotic cells include protozoa (i.e., Cryptosporidium and Giardia lamblia), plant and animal cells. Examples of some animal cells include cells in the nervous system such as astrocytes, oligodendrocytes, Schwann cells; autonomic neuron cells such as cholinergic neural cell, adrenergic neural cell, and peptidergic neural cell; sensory transducer cells such as olfactory cells, auditory cells, photoreceptors; hormone secreting cells such as somatotropes, lactotropes, thyrotropes, gonadotropes and corticotropes from the anterior pituitary glands, thyroid gland cells and adrenal gland cells; endocrine secretory epithelial cells such as mammary gland cells, lacrimal gland cells, ceruminous gland cells, eccrine sweat glands cells, and sebaceous gland cells; and other cells including osteoblasts, fibroblasts, blastomeres, hepatocytes, neuronal cells, oocytes, Chinese hamster ovary cell, blood cells such as erythrocytes, lymphocytes or monocytes, muscle cells such as myocytes, embryonic stem cells. Mammalian cells are an important example, being used in the screening of drugs. Other examples of eukaryotic cells include yeast cells and protozoa. Examples of plant cells include meristematic cells, parenchyma cells, collenchyma cells and sclerenchyma cells. The term ‘biological material’ additionally encompasses subcellular (intracellular) structures such as the nucleus, nucleolus, endoplasmic reticulum, centrosome, cytoskeleton, Golgi apparatus, mitochondrion, lysosome, peroxisome, vacuole, cell membrane, cytosol, cell wall, chloroplast, and fragments, derivatives, and mixtures thereof.

The microfiltration unit of the invention comprises a fluid chamber connected to an inlet for introducing the fluid to be filtered and an outlet for discharging filtered fluid. Within the fluid chamber, there is a filtration barrier for trapping the particles to be removed from the fluid. The pillars are aligned to form at least one row extending across the path of fluid flow (hereinafter ‘filtration path’). In other words, pillars are spatially distributed in a single file across the filtration path or, if more than one row is present, they are arranged to form several files. The filtration barrier comprises a plurality of pillars arranged to such that the pillars are substantially perpendicular to the filtration path within the fluid chamber. If the device has a planar configuration (e.g. in a pump assisted flow) wherein the fluid flows in the horizontal plane in the fluid chamber, the plurality of pillars may be arranged in the vertical plane to form a filtration barrier, intersecting the horizontal plane along which the fluid flows. While the filtration barrier may be in the vertical plane, individual pillars may be arranged either vertically across the height of the fluid chamber, or horizontally across the width of the fluid chamber. Alternatively, in a gravity assisted flow configuration, the fluid chamber may be orientated vertically so that fluid flows vertically downwards from the top to the bottom of the device. In this case, the pillars may be arranged in the horizontal plane to intersect the vertical direction of fluid flow.

Each row of pillars in the filtration barrier comprises at least one fine filtration section and at least one coarse filtration section. The fine filtration section comprises a group of pillars that are arranged parallel to each other and spaced apart at a distance to define gaps between adjacent pillars (hereinafter ‘inter-pillar gap’) that are sufficiently small to prevent particles that are to be filtered from the fluid from passing through the gaps, while at the same time allowing fluid in which the particles are present to pass through, thereby separating the particles from the fluid. The sample to be filtered may contain particles having a known or predetermined nominal size, e.g. based on statistical evaluation of size measurements that are derived from microscope observations of a sample. The size of inter-pillar gaps in the microfiltration unit may be made smaller than the nominal size of the particles. In a water sample containing unknown pathogen populations, for example, the fluid to be filtered may be introduced into the microfiltration unit without any prior knowledge of the size distribution of particles present in the liquid. In this case, the microfiltration unit may serve as a means to identify the size of particles present in the sample.

In one embodiment, the adjacent pillars of the fine filtration section are spaced apart from each other at a distance smaller than the predetermined nominal size of the particles to be filtered from the fluid. In general, gap sizes may be chosen based on the smallest dimension of the particle. For example, if particles to be filtered from the fluid are red blood cells that are known to be averagely 7.6 μm in diameter by 2.3 μm in thickness, then the inter-pillar gap size may be chosen to be about 2.3 μm or smaller. In one contemplated embodiment, the distance between adjacent pillars in the fine filtration section is between about 0.5 μm to about 1.0 p.m.

The coarse filtration section (hereinafter ‘by-pass section’) serves as a by-pass through which particles larger than a nominal size is able to escape. To achieve this effect, the group of pillars in the coarse filtration section are spaced apart from each other at a distance larger than the predetermined nominal size of the particles to be filtered from the fluid. Alternatively, in one embodiment, each coarse filtration section may simply comprise a gap. While the pillars may be spaced apart at a distance which is large enough for certain large particles to escape, it may also be designed small enough to trap larger particles which are to be prevented from moving through the filtration barrier. Taking blood again as an example, clumps of agglutinated red blood cells may be targeted for filtration and are to be prevented from leaving the filtration barrier. If the size of agglutinated clumps of red blood cells is known to be at least 50 μm or more at the filtration barrier, the coarse filtration section may be designed such that inter-pillar gap is no more than 50 μm in order to trap the agglutinated blood. The 50 μm gap will doubtless allow any particle smaller than 50 μm to leave, thereby giving rise to some loss of trapping efficiency as smaller particles will also escape through the coarse filtration section. However, this loss can be alleviated to some extent according to some embodiments as described. For example, several rows of pillars can be used to form the filtration barrier, each with staggered arrangement of fine and coarse filtration sections. Alternatively, by shaping the lateral side walls of the fluid chamber such that fluid flow is directed towards fine filtration sections in order that fine particles are first trapped in the fine filtration section before having any opportunity to escape via the coarse filtration section, it is also possible to reduce loss of trapping efficiency, for example.

The inter-pillar distance in the fine and the coarse filtration section can be varied according to the size and type of cell to be filtered. Particles having a known having a known range of sizes, e.g. a<diameter<b, may have a fine-filtration section in which the inter-pillar gap is smaller than a, and a coarse-filtration section in which the inter-pillar gap is larger than b. For example, Cryptosporidium parvum which are 2 to 6 μm in size may have a fine-filtration section in which the inter-pillar gap is smaller than 2 μm, and a coarse filtration section in which the inter-pillar gap is larger than 6 μm; for oval Giardia lamblia, which are 8-13 μm in length and 7 to 10 μm in width, a fine-filtration section in which the inter-pillar gap is smaller than 7 μm (smallest dimension), and a coarse filtration section in which the inter-pillar gap is larger than 13 μm (largest dimension) may be used.

In one embodiment, the filter configuration used for filtering protozoa cells comprises a fine filtration section having an inter-pillar distance of 1 μm, and a coarse filtration section having two sets of pillars, one set having an inter-pillar distance of 2 μm and another set having an inter-pillar distance of 4 μm. Hereinafter, filter configurations will be denoted by a μm^{f}: b μm^{c}: c μm^{c}, wherein superscript f denotes the inter-pillar gap of size a in the fine filtration section, and superscript c denotes the inter-pillar gap of size b and c in the coarse filtration section. Accordingly, this notation for the filter configuration in this embodiment is 1 μm^{f}: 2 μm^{c}: 4 μm^{c}. In another embodiment, the configuration for filtering rod-shaped E. coli particles, which typically have a cross-sectional diameter of about 1 μm and a length of several μm, as well as for filtering spherical microspheres which are 1 μm in diameter is 0.2 μm^{f}: 1.2 μm^{c}: 3.2 μm^{c}.

Generally, there are several factors which affect the performance of the microfiltration unit. These factors include distribution of particle size and their concentration, and volume of sample, etc. The final construction of the microfiltration unit is typically derived from a pre-selected design criterion, such as a level of trapping efficiency it is desired to achieve, or a particular pressure drop. Trapping efficiency and clog prevention are oppositely affected by the size of pillar gaps in the coarse filtration section. Trapping efficiency is lowered when the coarse filtration section is large, as a portion of particles tend to escape the filtration barrier into the filtrate without being caught by the fine filtration section. On the other hand, clog prevention improves with a large coarse filtration section, as fluid is able to flow through the filtration barrier even if the fine filtration sections in the filtration barrier is fully occupied. Thus, in order to achieve a good balance between trapping efficiency and clog prevention, the proportion of fine filtration sections and coarse filtration sections may be optimised based on a given particle with a known size distribution.

In one embodiment, the optimal ratio of total coarse filtration section to total fine filtration section length may be determined by theoretical trapping efficiency, which is determined by the formula (I):

$$Trapping Efficiency = \frac{\begin{matrix}number of streamlines \\ passing through fine filter\end{matrix}}{\begin{matrix}Total number of streamlines passing \\ through fine and coarse filter\end{matrix}}$$

Theoretical trapping efficiency is preferably in the desirable range of actual trapping efficiency. In actual practice, it is known that the smaller the inter-pillar width, the better the trapping efficiency. But when pillar-width is small, pressure drop increases, thereby raising the requirement that each individual pillar unit must have sufficient mechanical strength to withstand the hydrostatic forces. This may be provided, for example, by a minimum pillar width to ensure that each individual pillar is strong enough to withstand shear and bending forces caused by the fluid flow.

Without wishing to be bound by theory, it has been found that favourable filter performance can be obtained if the proportion of fine filtration sections and coarse filtration sections in each row of pillars falls within the range according to the following empirically derived formula (II):

$$0.3 < \frac{\begin{matrix}{\sum }_{ }^{ } Inter \text{-} pillar gaps in \\ the fine filtration section\end{matrix}}{\begin{matrix}{\sum }_{ }^{ } Inter \text{-} pillar gaps in \\ the coarse filtration section\end{matrix}} < 1.7$$

In general, this formula may be applicable to the case in which the inter-pillar gap size of the coarse filtration section is less than 10 times the size of the inter-pillar gap size in the fine filtration section. As an illustration of this formula, consider that in one row of pillars, there may be arranged 1000 gaps with a size of 0.5 each forming the fine filtration section, and 500 gaps with a size of 2 μm each forming the coarse filtration section. Accordingly, the ratio according to the above formula would be 0.5, which is within the range in which a favourable balance of trapping efficiency and clogging sensitivity is achieved.

The filtration barrier comprises at least a single row of pillars for carrying out filtration. However, filtration capacity of a single row of pillars is limited, especially if the fine filtration section is relatively small as it would be quickly occupied with trapped particles. In order to improve filtration capacity, several rows of pillars may be used. In one embodiment, the filtration barrier comprises at least two rows of pillars, comprising an upstream row (nearer the inlet) and a downstream row (nearer the outlet). In other embodiments, several pairs of upstream-downstream rows may be used.

The presence of by-pass sections results in lower trapping efficiency as particles tend to escape via the coarse filtration section due to the lower flow resistance in the coarse filtration section. In order to improve trapping efficiency, several embodiments have been contemplated as follows.

In one embodiment, the fine filtration sections and the coarse filtration sections are arranged in an alternating (staggered) formation, wherein the position of the fine filtration section and the coarse filtration section alternates from one row to the next, thereby establishing a tortuous (i.e. meandering) filtration path in the filtration barrier. In other words, the position of the fine filtration sections in a downstream row is arranged to correspond or to shadow the position of the coarse filtration section in the upstream row. The inventors have found that such a configuration of alternating fine and coarse filtration sections improves trapping efficiency because particles which manage to escape from the coarse filtration section of each row immediately encounters the fine filtration section in the next row of pillars along the filtration path. In this manner, the fluid containing the particles is successively filtered as it courses through the filtration barrier. Additionally, there are no corners or bends at which entrapment of air pockets can occur with this arrangement.

In a further embodiment, the downstream fine filtration section shadowing the upstream coarse filtration section has a larger cross-sectional area than the coarse filtration section in the upstream row in order to create overlapping regions of fine filtration sections within the filtration barrier downstream of every coarse filtration region.

Various arrangements of fine and coarse filtration sections have been contemplated. In one embodiment, the upstream row of pillars comprises two coarse filtration sections, each arranged at one end of the row, and a fine filtration section arranged in the middle of the row. The downstream row has, according to the staggered/alternating configuration, two fine filtration sections, each arranged at one end of the row, and a coarse filtration section arranged in the middle of the row.

It is also found that the trapping efficiency and flow characteristics of the fluid sample is further improved by having coarse filtration sections in which the inter-pillar gaps are progressively wider nearer the lateral walls of the fluid chamber. Accordingly, in a further embodiment, the distance between adjacent pillars in each of the coarse filtration sections increases towards the end of the row. In a specific implementation, one group of coarse filtration section pillars located beside the fine filtration section are spaced apart at a distance of 2 μm, while a second group of coarse filtration section pillars located between the fluid chamber walls and the 2 μm spaced apart pillars are spaced apart from each other at a distance of about 4 p.m. Various coarse filter configurations are illustrated in the Examples.

‘Pillars’ as described herein refer to discrete elements that are arranged closely to define small gaps of a pre-determined size between adjacent elements which allow only particles of a certain size (or no particles at all) to move through. These discrete elements may have any type of geometry, including block rectangular shapes, polygonal shapes (e.g. diamond), cylindrical or elliptical shapes, as well as any other suitable customised irregular shapes.

The geometry of the pillars were found to significantly affect the flow resistance of the entire microfiltration unit as well as the trapping efficiency of the filtration barrier. One geometry conferring advantageous characteristics comprises a cross-sectional shape resembling a raindrop, having a pointed front section that is arranged to be incident to fluid flow in the fluid chamber, an elongated middle section, and a substantially rounded rear section. It is found that a pointed front section greatly improves the ability of the pillars to trap particles as compared to a rectangular block pillar. It also reduces flow pressure build up and reduces the likelihood of trapped particles being washed away by the tangential flow of fluid across the row of pillars. The elongated middle section reduces cell loss caused by cell motility through inter-pillar gaps. The rounded rear section helps to reduce bubble generation during sample injection.

The pillars may be fabricated according to any micromachining technique known in the art. For example, the pillars may be formed by deep reactive ion etching (RIE) on silicon and conformal deposition. Examples of the fabrication process are provided in Example 1 below.

In order to achieve desired fluid flow characteristics in the fluid chamber, e.g. to vary the rate of flow of the fluid, the lateral walls defining the fluid chamber may be designed to have wide and narrow sections. For example, the lateral walls defining the fluid chamber may be tapered to define a narrow channel within the fluid chamber in order to accelerate the fluid. In one embodiment, the tapered section of the fluid chamber is located immediately upstream of the fine filtration sections of the first row of pillars in the filtration barrier.

In another embodiment, the part of the fluid chamber in which the filtration barrier is located comprises an enlarged cross-sectional area relative to the cross-sectional area of the inlet through which fluid is introduced into the fluid chamber. The enlarged cross-sectional area reduces the speed at which fluid flows through the filtration barrier and thus greatly reduces flow pressure in the filtration barrier. In this manner, the filtration barrier becomes less sensitive to spikes in fluid pressure when fluid samples are injected into the unit, and thereby less prone to breakage.

When filtering fluid samples containing large particles, e.g. sediments in water samples obtained from muddy water sources, the large particles can be first separated from the fluid by implementing a coarse filter upstream of the filtration barrier. The coarse filter helps to ensure that the fluid reaching the filtration barrier contains essentially only small particles which the filtration barrier is designed to filter, and not large particles which would rapidly clog even the coarse filtration sections in the filtration barrier.

When the microfiltration unit is implemented as a stand alone filtration device, a housing may be provided to accommodate the fluid chamber and the filtration barrier. In one embodiment, the housing comprises three-sections: a planar base substrate, an intermediate planar member attached to the planar base substrate, and a transparent cover attached to the intermediate planar member. The intermediate planar member is hollow in the centre with lateral sidewalls of the planar member surrounding the hollow, said hollow being defined through the thickness of the planar member. This three-piece configuration can be easily fabricated and assembled by employing standard lamination and bonding techniques known in the art. An alternative design comprises a monolithically formed base substrate and intermediate planar member, requiring only the attachment of the transparent cover in order to obtain a complete device. For certain applications in which filtered particles are to be harvested, it is preferable to have removable covers which are conveniently removed and the filtered particles are readily accessible.

In order to form complete microfluidic systems (also known as a lab-on-a-chip) capable of performing a series of unit operations on a sample fluid, It is also possible to integrate the microfiltration unit of the invention with other microfluidic unit operation modules. For example, in order to carry out blood typing, the microfiltration unit according to the invention can be integrated with micromixers for mixing a blood sample with each of the four known types of serum (namely, serums for blood groups A, B, AB and O) as a first step. The mixture of blood and serum is then diverted into a microreactor where agglutination is allowed to take place as a second step. Finally, as a third step, the mixture of blood, serum and agglutinated blood if any, are directed into the microfiltration unit of the invention to determine whether agglutination has taken place. Accordingly, in one embodiment, the microfiltration unit according to the invention is operably connected to one or more microfluidic unit operations modules for processing biological material. Examples of microfluidic operation modules include micromixers, micropumps and microreactors, for example.

The microfiltration unit according to the invention can be used to concentrate particles present in a fluid as well as to purify a given fluid. Accordingly, one aspect of the invention is directed to a method of purifying a fluid containing particles having a predetermined nominal size or range of sizes. Another aspect of the invention is directed to a method of extracting particles of a predetermined nominal size or range of sizes from a fluid. Both methods comprise passing the fluid to be filtered into a microfluidic filtration unit according to the invention. Fluid is introduced into the fluid chamber via one or more inlet ports. Filtration can be carried out under the influence of gravity and capillary forces, or it may be pump-driven.

In some biomedical applications, the microfiltration unit according to the invention may be used for processing biological fluids such as blood, urine, semen, sweat, cell cultures, as well as a fluid sample containing a biological tissue. Applications that involve the processing of such particles include blood plasma separation, PCR product clean up, dialysis and drug discovery. For such applications, particles to be filtered typically comprise blood plasma, eukaryotic cells, biological tissue fragments as well as intracellular organelles. In some embodiments, eukaryotic cells include red blood cells and white blood cells.

The microfiltration unit may also be used for the detection of pathogens in a fluid sample. For example, water samples obtained from a river suspected of containing disease-causing pathogens, or food samples which have caused food poisoning can be screened, for example. Examples of pathogens which can be screened include various types of bacteria, protozoa and virus.

### BRIEF DESCRIPTION OF THE DRAWINGS

Preferred embodiments will now be described by way of non-limiting examples only, with reference to the accompanying drawings, in which:

FIG. 1 shows a perspective view of a microfluidic device according to an exemplary embodiment of the invention;

FIGS. 2A and 2B shows top view of the fluid chamber of a microfiltration unit according to the invention; the fluid chamber in FIG. 2A comprises a single row of pillars, whereas the fluid chamber in FIG. 2B comprises two rows of pillars. FIG. 2C shows the flow pattern of particles in a filtration barrier comprising two-rows of pillars.

FIGS. 3A, 3B and 3C depict various arrangements of the rows of pillars within the fluid chamber.

FIG. 4 shows the fluid flow profile in the fluid chamber of a microfiltration unit according to the embodiment shown in FIG. 2B

FIG. 5 shows a table containing the performance data of 4 different microfiltration units having different fine/coarse filtration sections.

FIG. 6 shows a graph depicting the performance characteristics of various microfiltration units with different proportions of fine/coarse filtration sections.

FIG. 7 depicts various shapes which the pillars in the filtration barrier can assume.

FIG. 8 shows how raindrop shaped pillars are adapted to trap particles.

FIG. 9A to 9F depict a process scheme for fabricating the microfiltration unit according to the invention.

FIG. 10 is a schematic depiction of a 200 mm silicon wafer comprising LP nitride layer and thermal oxide layer.

FIG. 11A to 11I are electron microscope photographs showing various perspectives of raindrop shaped pillars spaced apart at 1 μm, 0.4 μm, and 0.1

FIG. 12 shows a cross-sectional view of a finished microfiltration unit.

FIG. 13A shows a top view of a conventional ‘zig-zag’ filter without coarse filters in its filtration barrier. FIG. 13B shows a graph of Pressure prop vs. Time for an experiment carried out with flow rates of 1 μl/min and 5 μl/min on the conventional ‘zig-zag’ filter without by-pass coarse sections and a standalone microfiltration unit having by-pass coarse sections according to the invention.

FIG. 14 shows a graph of Pressure prop vs. Time for an experiment carried out on 4 identical microfiltration units according to the invention under different conditions to determine pressure drop behaviour when beads of various sizes were introduced.

FIG. 15 depicts a graph of Trapping Efficiency vs. Cell Concentration for an experiment carried out on a standalone microfiltration chip according to the invention with pillar configuration according to Design 1 and Design 2, using mixtures containing different concentrations of protozoa cells.

FIG. 16A depicts the graph of Trapping Efficiency vs. No. of Injected Beads. FIG. 16B depicts the position of 1 μm beads in the inter-pillar gaps. FIG. 1016C depicts E. Coli cells located in the fine filtration section of a microfiltration unit.

### DETAILED DESCRIPTION

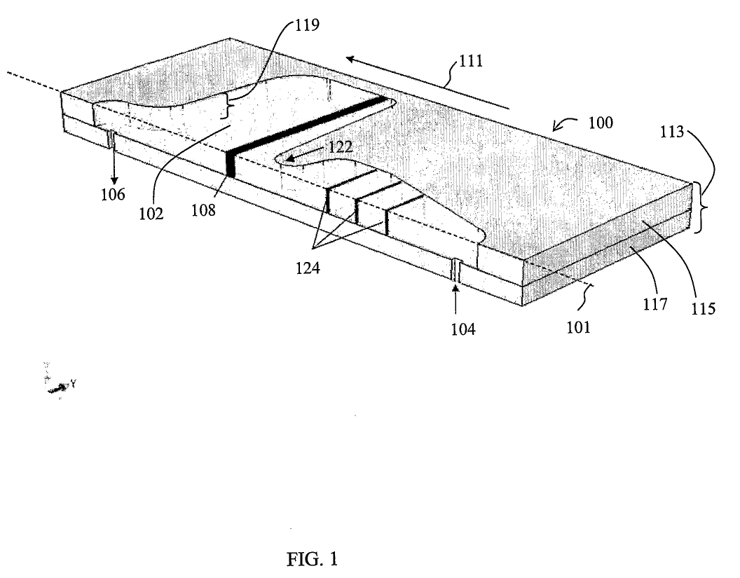

A perspective of a microfiltration unit 100 according to a first embodiment of the present invention is depicted in FIG. 1. The figure shows a right-half section of the microfiltration unit according to the invention divided along the line of symmetry 101 as indicated by the dotted line. The microfiltration unit comprises a fluid chamber 102 wherein fluid is introduced into the fluid chamber 102 via an inlet 104 and an outlet 106, each located at opposite ends of the fluid chamber in order to define a sufficiently long filtration path as fluid flows from inlet to outlet in the direction as shown by the arrow 111. A filtration barrier 108 comprises pillars aligned in one or more rows and arranged across the path of fluid flow. Each row of pillars comprise one or more fine filtration sections having closely arranged pillars for trapping particles or at least preventing their movement through the filtration barrier, and one or more coarse filtration sections comprising pillars that are spaced apart sufficiently to permit the movement of particles (not shown in this figure). The fluid chamber is encased within a housing 113 made up of a planar base substrate 115 and an intermediate planar member 117 that has a hollow section defined through its body. The hollow section is surround by lateral side walls 119, which may be designed to enhance fluid flow characteristics. In this embodiment, the lateral walls 119 are made to define a constriction 122 immediately upstream of fine filtration sections in the filtration barrier 108. This serves to accelerate the fluid such that it is directed rapidly onto the fine filtration section so that particles are filtered from the fluid. A transparent cover (not shown) may be arranged over the intermediate planar member to seal the fluid chamber, thereby forming a complete microfiltration unit.

Optionally, coarse filters can be installed upstream of the filtration barrier to filter out large particles which can potentially clog even the coarse filtration section in the filtration barrier. In this embodiment, 3 sets of coarse filters 124 were provided. The inlet opens into a tapered section of the fluid chamber where the coarse filters are located. The coarse filter nearest to the inlet has the largest filtration gap of 50 μm, the second coarse filter has a filtration gap of 20 μm and the third coarse filter has a filtration gap of 10 μm. By implementing these coarse, filters, it is assured that the fluid reaching the filtration barrier contains only particles smaller than 10 μm.

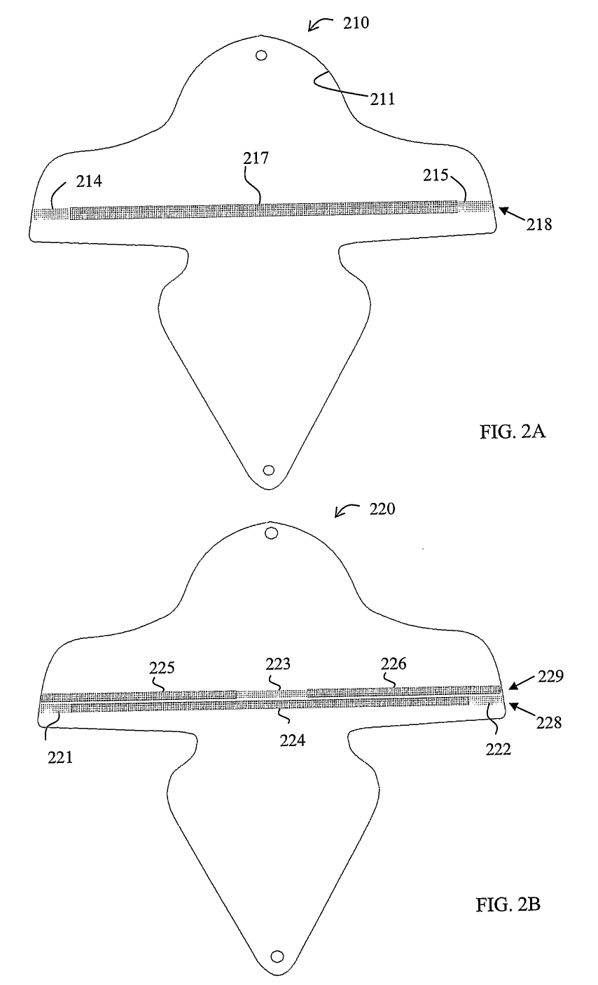

FIG. 2A and FIG. 2B depict two embodiments of the invention having different filtration barriers. FIG. 2A shows the outline of a fluid chamber 211 having a filtration barrier comprising a single row of pillars 218. This row of pillars comprise two coarse filtration sections 214 and 215, each arranged at an edge of the row, and arranged between a coarse filtration section 217. After being in used for a while, the fine filtration section 217 becomes clogged with trapped particles. The coarse filtration sections 214, 215 comprise pillars spaced sufficiently far apart to allow particles to get through, so that even after the fine filtration section is clogged, fluid is allowed to move through the filtration barrier via the coarse filtration sections 214, 215. In this manner, the coarse filtration sections act as vents to ease off hydrodynamic pressure when the fine filtration section reaches its maximum filtration capacity, thereby preventing the microfiltration unit from breaking due to spikes in hydrodynamic pressure caused by clogging. In the embodiment shown in FIG. 2B, the filtration barrier is depicted to have two rows of pillars comprising one upstream row 2288 and one downstream row 229. The arrangement of the fine and coarse filtration sections in the upstream row 228 is the same as that in FIG. 2A, wherein coarse filtration sections 221 and 222 are located at the sides of the row, while the fine filtration section 224 is located in the middle of the row. The downstream row 229 comprises two fine filtration sections 225, 226 that are arranged at the sides of the row, while a coarse filtration section 223 is arranged in the middle of the row. It will be noted that the fine and coarse filtration sections are arranged in an alternating manner from one row of pillars to the next. It can also be said that the coarse filtration section in the upstream row is “shadowed” by a fine filtration section in the downstream row. Such an arrangement enables particles escaping from the coarse filtration section 221, 222 of the upstream row 228 to be caught in the downstream row, thereby minimising the loss of particles.

FIG. 2C shows in detail the pair of upstream row of pillars and downstream row of pillars as described in FIG. 2B. The upstream row 231 comprises coarse filtration sections 234, 236 arranged at the ends of the row adjacent to the fluid chamber walls 250. The downstream row 232 comprises fine filtration sections 244, 246 arranged immediately downstream of the coarse filtration sections in upstream row 231. A coarse filtration section 248 is arranged between the two fine filtration sections 244, 246. The fine filtration section comprises pillars arranged sufficiently close to define gaps which particles are unable to move through. The coarse filtration section comprises pillars spaced sufficiently wide apart to define gaps which particles are able to move through. The two rows of pillars are arranged in the path of fluid flow as indicated by the arrow, and fluid streamlines (a) bring particles to the fine filtration section in the upstream row, thereby causing the particles to be trapped at the fine filtration section. Some particles avoid entirely the fine filtration section and are swept by streamline (b) onto the fine filtration section 246 in the downstream row 232, thereby causing the particle to be trapped. Some particles following streamline (c) are lost in the filtrate as they avoid fine filtration sections of both the upstream row 231 and the downstream row 232, travelling only through the coarse filtration sections. This double-layered, or double-row configuration has a longer overall length available for filtration, and the coarse filtration sections act as by-pass vents to reduce the build up of pressure due to accumulation of particles at the fine filtration sections. The loss of particles can be minimised by optimising the proportion and porosity of the coarse filtration sections.

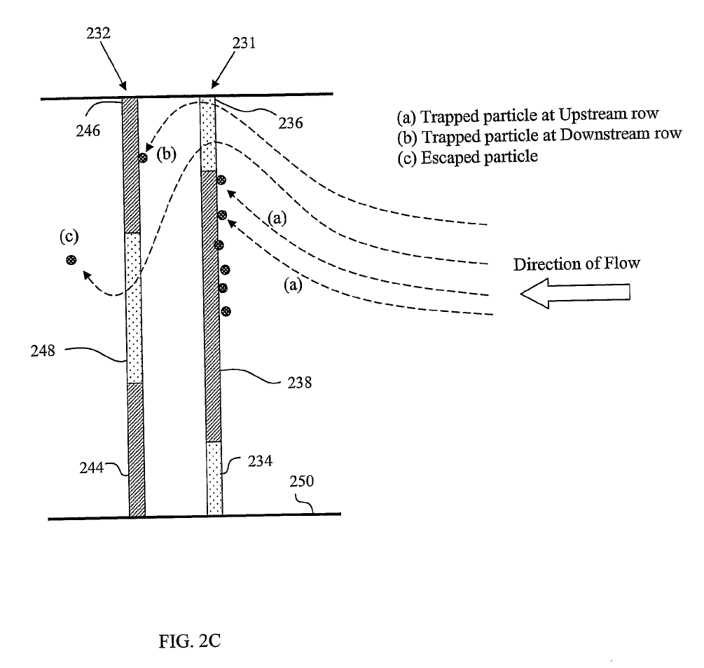

FIGS. 3A, 3B and 3C depict various possible arrangements of the pillars forming the filtration barrier. FIG. 3A shows an arrangement comprising four rows of pillars 318 arranged between lateral walls 311 of the fluid chamber. Each row comprises one fine filtration section and one coarse filtration section, arranged in an alternating fashion. Fluid flowing in the direction as indicated by the arrow 301 is initially directed towards the fine filtration section 315 in the first row of pillars. Particles are allowed to move across the first row via coarse filtration section 316. As fine filtration section 317 is arranged immediately downstream of the coarse filtration section 316, particles which escape from the first row of pillars is filtered again, thereby recovering any lost particle. Coarse filtration section 318 allows particles to move through the second row, but once again, it is filtered by the fine filtration section in the third row of pillars. In this manner, successive filtration is carried out via a zigzag filtration route established by the alternating arrangement of fine and coarse filtration sections, while preventing clogging from taking place at the same time. FIG. 3B shows another arrangement for the filtration barrier in which four rows of pillars 328 are arranged in a sloping manner, away from the direction of fluid flow 301. In this embodiment, the rows are sloped downwards, the coarse filtration sections 326, 328 being located at the end of the slope. In accordance with the alternating (staggered) layout, the coarse filtration section 326 is shadowed by a fine filtration section 327 in the next row. FIG. 3C depicts yet another embodiment in which the first row of pillars comprise coarse filtration sections 331, 333, 335 which are located at the edge of the row, and fine filtration section 332, 334, 336 arranged in the middle of the row, as described in FIG. 2A and FIG. 2B. This embodiment includes additional rows of pillars 338 to improve filtration efficiency.

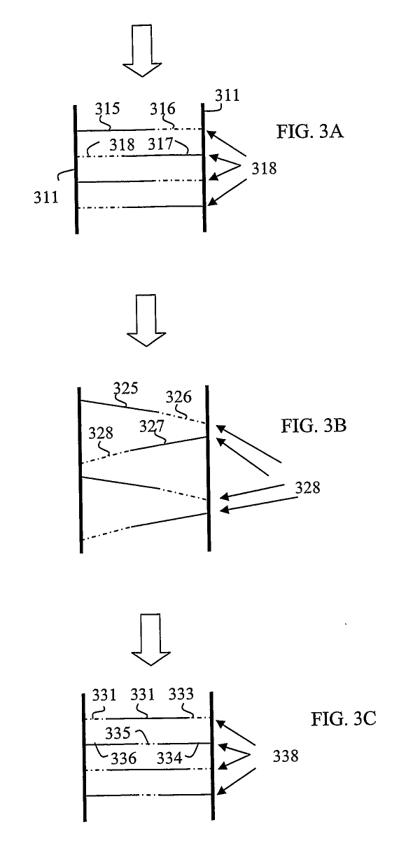

Computer simulation was carried out to study the flow characteristics of the microfiltration unit having the structure as shown in 2B. The fluid flow profile is shown in FIG. 4. Streamlines of fluid flow are depicted by white lines with arrows 401. Due to the high flow resistance at the location of the fine filtration section 403 in the first row of pillars, fluid tends to travel around the fine filtration section by flowing through the coarse filtration section 405 where flow resistance is lower. Particles escaping the coarse filtration section 405 are filtered by the fine filtration section 407 in the second row of pillars. Fluid between the two rows of pillars also tend to exit the second row of pillars via the coarse filtration section 409 due to the reduced flow resistance, as can be seen from the direction of streamlines between the two rows of pillars as well as the darkened region at the location of the coarse filtration section 409 in the second row. Fluid flow rate is highest at the constriction 411 in the fluid chamber.

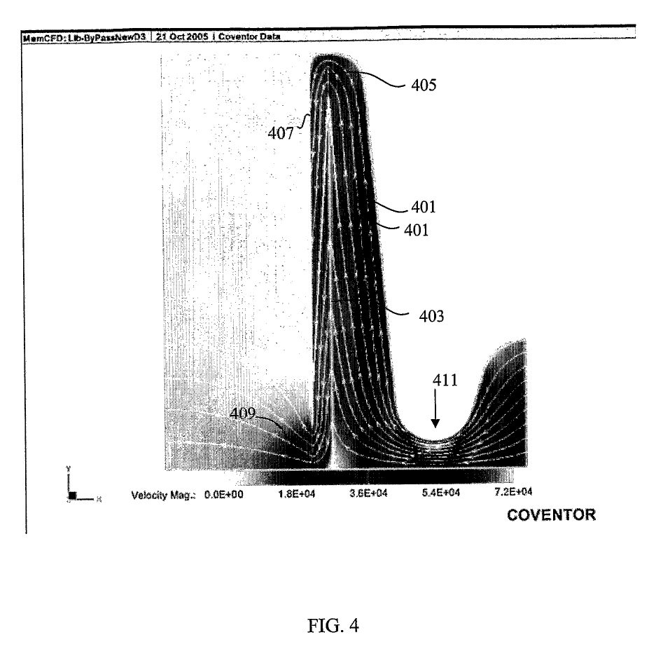

The simulation was extended to 4 different microfiltration units each having a different proportion of fine/coarse filtration sections. The table in FIG. 5 shows numerical data obtained from the simulation. The set of 3 numbers under the ‘Configuration’ column refer, respectively, to the number of 4 μm, 2 μm and 0.5 μm gaps. The 0.5 μm gaps formed the fine filtration section, while the 4 μm and 2 μm gaps formed the coarse filtration sections. The configuration 150/300/4050 would represent a two rows of pillars having a forming a total of 150 coarse filtration gaps of 4 μm, 300 coarse filtration gaps of 2 μm, and 4050 filtration gaps of 0.5 μm. The first configuration indicated by 0/0/4500 is a control in which the filtration barrier comprises only a fine filtration section comprising 4500 gaps having a size of 0.5 μm. It will be noted from these simulation results that all three configurations have a consistently lower mean pressure drop at their respective filter elements as compared to the baseline configuration. Furthermore, as the number of coarse filtration section gaps increased, the pressure drop decreases, and at the same time, bypass losses due to particles escaping from the coarse filtration section also increased.

Depending on the application for which the microfiltration unit is used, the optimal proportion of fine/coarse filtration sections can be determined from such a simulation. For example, if it is intended to purify a fluid by extracting contaminant particles, it is preferable to have a small coarse filtration section. However, if large quantities of fluid are to be processed, then it may be preferable to have a larger number of coarse filtration gaps in order to lower pressure drop. Additionally, it is possible to determine the minimum number of stages/rows of pillars necessary for achieving a targeted percentage of particle recovery.

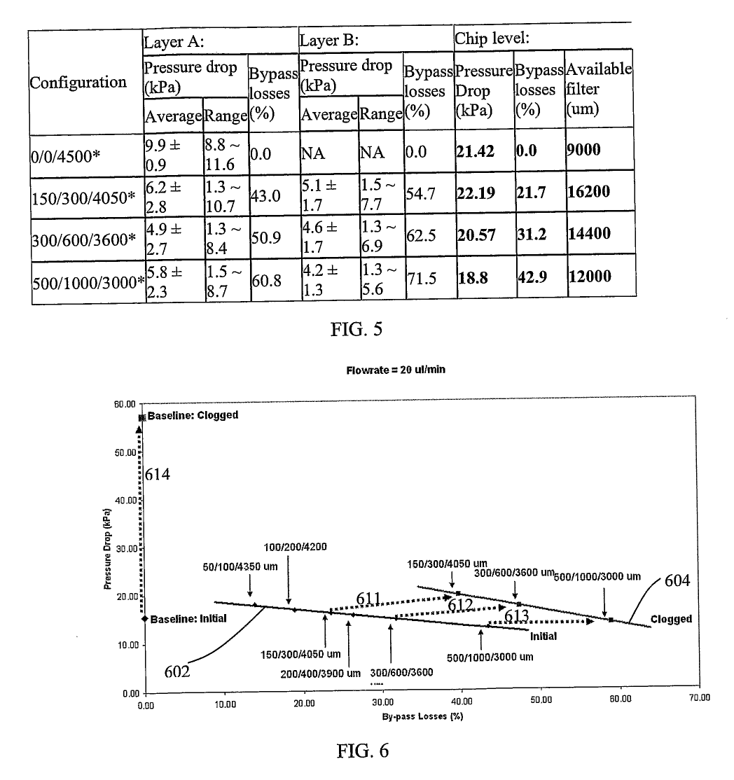

FIG. 6 depicts the performance graph of various microfiltration units with different proportions of fine/coarse filtration sections. The results were obtained through computer simulation based on the software Coventorware™ 2005. Line 602 represents the initial performance of these units, while line 604 represents their performance when the maximum filtration capacity is reached, i.e. clogging of all available fine filtration sections occurs. It can be observed that the units using a combination coarse filtration section by-passes display a very slight increase in hydrodynamic pressure as compared to the baseline configuration. In fact, for a given configuration, pressure drop remains fairly constant during the entire duration of operation. In the embodiment depicted by line 611, the pressure drop maintained at about 18 kPa; in the embodiment depicted by line 612, the pressure drop maintained at about 15 kPa; in the embodiment depicted by line 613, the pressure drop maintained at about 13 kPa. For the control/baseline example, the pressure increases up to more than 3 times its initial level when clogging occurs, as indicated by line 614. Furthermore, losses increases as the effects of clogging increases, as more particles are permitted to escape to prevent the build up of pressure.

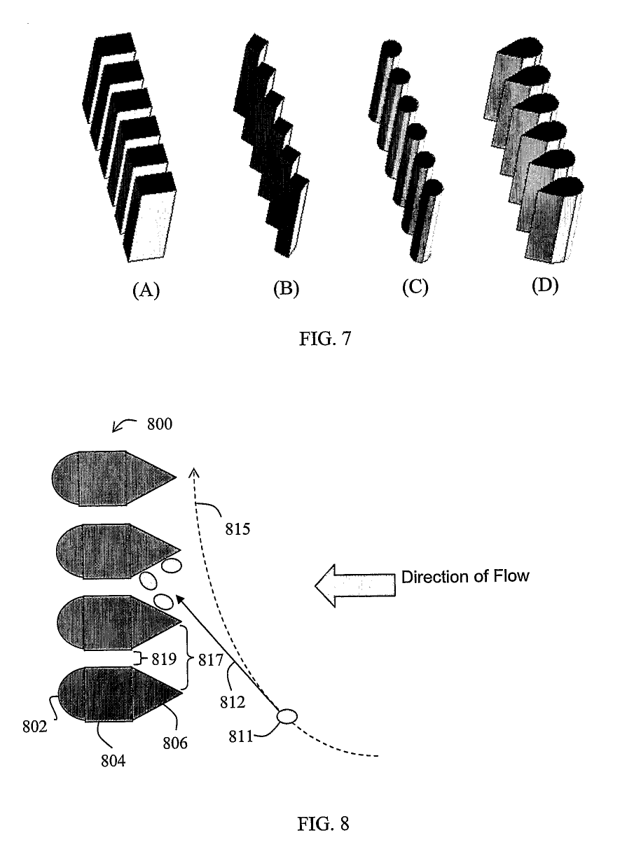

FIG. 7 depicts various shapes that can be assumed by the pillars that are used to form the filtration barrier in the present invention. In general, particles comprising live cells would require the use of pillars with sufficient depth as it would impede the loss of particles through cell motility. FIG. 7A shows block-shaped pillars, with their lengths orientated vertically in the fluid chamber, with a flat surface facing the direction of fluid flow. FIG. 7B show diamond shaped pillars with a pointed edge facing the direction of fluid flow. FIG. 7C shows cylindrical pillars. FIG. 7D shows one preferred embodiment in which the pillars assume a raindrop shape.

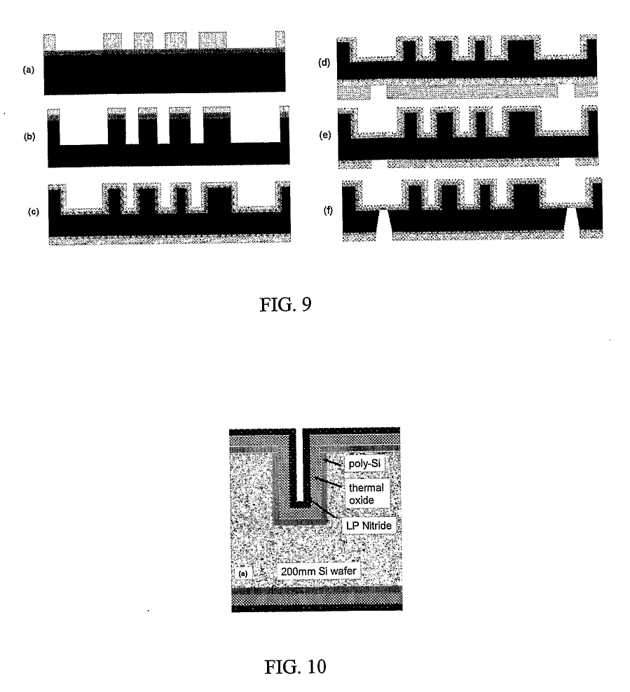

FIG. 8 explains in greater detail the function of filtration barriers comprising raindrop-shaped pillars. The row of pillars 800 each comprises a pointed front section 802, for example formed from a triangular section, a middle rectangular block section 804, and a rear rounded section 806 that is arranged to face oncoming fluid. Particle 811 in the fluid is swept towards the pillars along the trajectory indicated by line 812 and is trapped between adjacent pillars 813, 815. The pointed front sections between adjacent pillars are tapered outwards to define a trapping region 817 that helps to trap particles due to the inertial effects of the particles, and to retain trapped particles so that they are not swept away by tangential fluid flow as indicated by the dotted line 819. The inter-pillar gap 819 is smaller than the nominal size of the particles to be trapped so that trapped particles are unable to move through the inter-pillar gaps 819.

### Example 1

### Fabrication

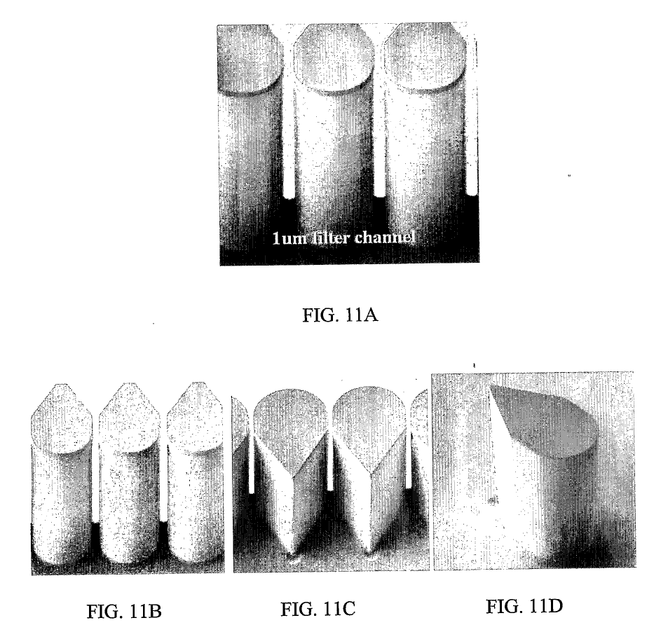

The raindrop shaped pillars were fabricated by standard micromachining techniques. According to one process scheme which the inventors have developed for this invention, the following process steps were carried out to fabricate the pillars as shown in FIG. 9. Firstly, a resist mask was patterned, using silicon dioxide as hard mask (FIG. 9A). The oxide hard mask was subsequently opened and deep silicon etching was carried out to achieve an etch depth of about 30 μm (FIG. 9B). The oxide hard mask was then removed and the etched-out gaps were filled (FIG. 9C). By employing conformal deposition to fill the gaps, filter channel gaps were accurately fabricated down to sub-micron ranges. The subsequent step comprises backside wafer patterning to form the inlet and outlet opening of the fluid chamber (FIG. 9D). The nitride and oxide mask is then opened (FIG. 9E) and etching is performed (e.g. using KOH on Si) to form the inlet and outlet (FIG. 9F). Finally, the lamination and bonding of a glass cover over the fluid chamber is carried out.

A detailed explanation of the fabrication of microfiltration unit according to the above process flow will now be described. After lithography, patterning of the wafers with the rain drop shape pillar patterns was carried out. Initially, 1 μm of oxide hard mask is etched away. For deep silicon etching, a dual passivation etch chemistry was carried out which provides O₂ passivation during the etch cycle, followed by C₄F₈ gas to deposit an additional Teflon passivation layer before the next etch cycle starts. This eliminated the formation of self-limiting V-shaped filter channels. Etching of silicon under silicon-dioxide hard mask enabled better control for gap sizes and well defined gap edges compared to etching under photoresist mask. With optimized silicon etch process, vertical filter channels of 1 μm gap and less and chamber depth of 30 μm were achieved. A filter gap height of about 22 μm was achieved with 30 μm chamber depth, the difference being due to the reactive ion etching (RIE) lag effect.

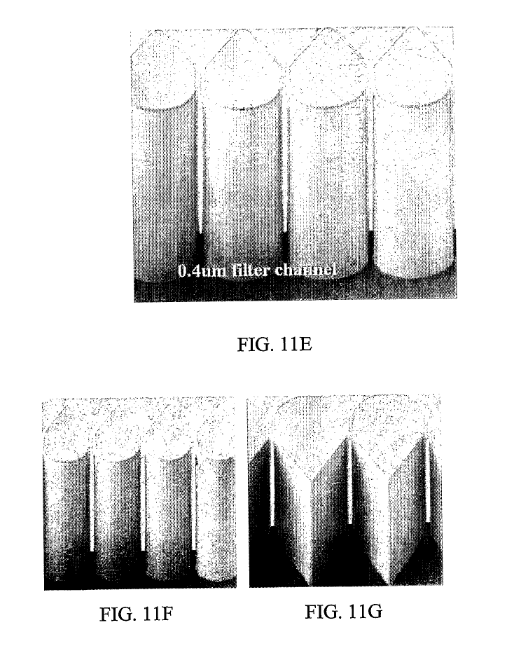

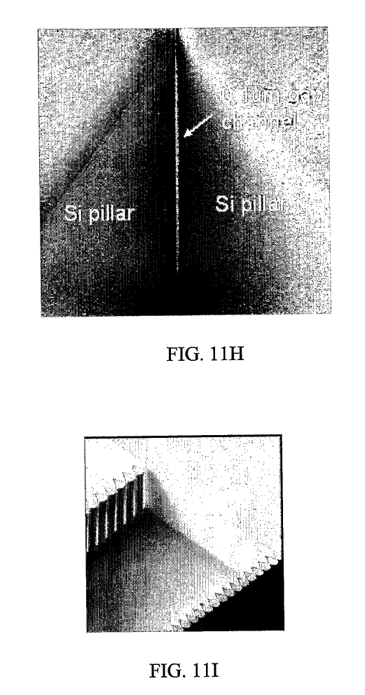

After completing the silicon etching for forming the pillar structures, cleaning is performed using piranha solution to obtain polymer/residue-free Si microstructures. Depending on the size of the filtration gap of the fine filtration region, a combination of silica layers such as thermal oxide, silicon nitride (via LPCVD), poly-silicon can be grown for pre-calculated thicknesses. This approach has provided wide applicability to achieve various filter gaps from microns down to sub-micron dimensions. For example, if gap dimensions are not sufficiently small, growth-based gap fill (or gap reduction) techniques may be applied to reduce the filtration gaps formed between the fabricated Si-pillars to the required micron or sub-micron dimensions. Examples of gap fill techniques that can be used presently include sub-atmospheric chemical vapour deposition (SACVD), and low-pressure chemical vapor deposition using tetra-ethyl-ortho-silicate (LPTEOS). These techniques are described in the prior art, for example see Nag et al. (“Comparative Evaluation of Gap-Fill Dielectrics in Shallow Trench Isolation for Sub-0.25 μm Technologies”, 1996 IEEE, IEDM 96, 841-844). The schematic depiction of this process module approach is shown in FIG. 10. This approach has enabled the fabrication of wide Si chambers and Si pillars with sub-micron filtration gaps with one mask process flow and is a cost effective process technology. Photographs of raindrop shaped pillars fabricated according to this procedure is shown in FIG. 11A to FIG. 11D illustrating different perspectives of pillars that are spaced apart at a distance of 1 μm, while FIG. 11E to FIG. 11F show different perspectives of pillars spaced apart at a distance of 0.4 μm. Ultra fine filtration pillars spaced apart to form inter-pillar gaps sizes of 0.1 μm width and 15 μm height were also fabricated, as shown in FIG. 11H. These fabrication examples confirmed the extendibility of this process to a wide range of applications. A perspective view of rows of raindrop pillars arranged in a filtration barrier is shown in FIG. 11I.

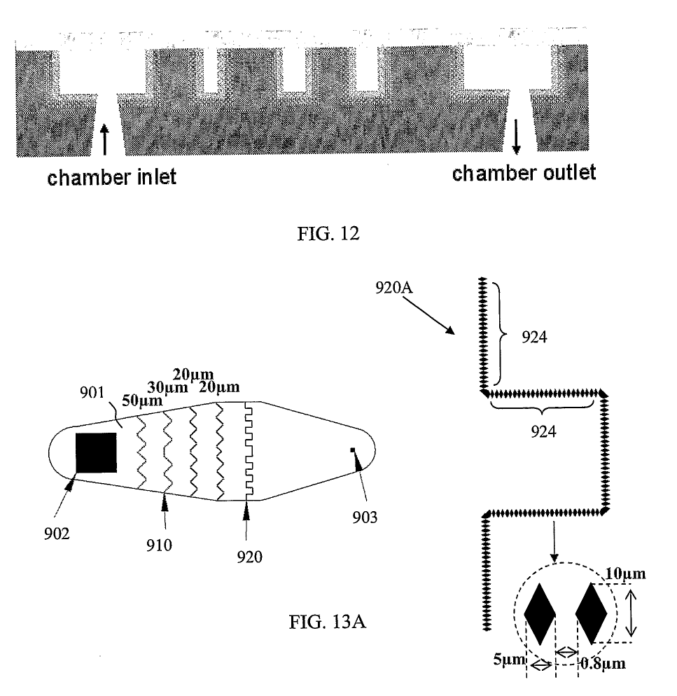

After completing the fabrication of filter structures/chamber on the wafer front side as explained above, backside processing was carried out to form the inlet/outlets for chambers by using KOH etching of silicon (for process flow refer to FIG. 9A to 9F). The dielectric stack etching for Si etching and subsequent KOH wet etching of Si was found to be critical to obtain good physical yield of the filter chip devices. These two etch processes were optimized and device physical yield was maximized. Residual layers of oxide and nitride were finally etched away for the through opening of the inlet/outlets. Final chip fabrication is accomplished by capping the wafer front-side by anodic glass bonding and dicing. The cross-sectional view of the finished microfiltration unit is shown in FIG. 12.

In summary, the above process flow for forming rain drop shape pillar type silicon by-pass filter chip was designed to achieve both micron and sub-micron size filtration gaps. The entire filter chip fabrication is accomplished in two stages. In the first stage, silicon micro-pillars and chambers are realized on the wafer front side using pattern transfer technology. In the second stage, inlets/outlets to the front side chambers are made on the wafer back-side. Initially, filtration gaps are formed between pillar elements with inter-pillar gap dimensions (about 1 μm for the fine filter region) that provides uniform vertical profiles throughout the entire filter gap from top to bottom. Based on the preliminary experiments and Si deep RIE process optimization, it was observed that for the raindrop shape Si-pillar type by-pass filter of 30 μm chamber depth, the etch profile of the filter gaps is uniformly vertical and straight for up to 1 μm gap dimension. The fabrication process requires only non-critical lithography mask which is of very low cost, thus reducing overall manufacturing cost of the microfiltration units.

### Example 2

### Characterization

### i) Pressure Drop Test

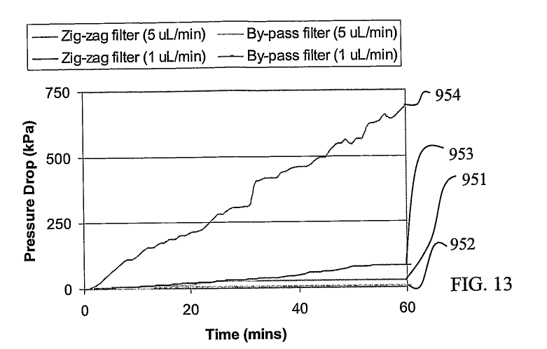

An experiment was carried out to compare pressure drop characteristics between the microfiltration unit according to the present invention and a microfiltration unit without by-pass coarse sections. For the experiment, a microfiltration unit comprising diamond shaped pillars arranged in a zig-zag configuration without by-pass ('zig-zag filter', Chip 1) as shown in FIG. 13A was fabricated to serve as a control for the experiment. The zig-zag filter 900 comprises a fluid chamber 901 and a coarse filtration section 910 having four rows of pillars, the row nearest to the inlet 902 having a filter gap size of 50 μm, the next row having a gap size of 30 μm, and the next two rows both having the same gap size of 20 μm. Downstream of the coarse filtration section is a fine filtration region 920 comprising pillars arranged in a zig-zag formation. As can be seen from the magnified FIG. 920A, the fine filtration region 920 comprises diamond-shaped pillars 922, which are 5 μm in width and 10 μm in length, and spaced apart to define an inter-pillar gap size of 0.8 μm. Each section 924 of the fine filter region comprises 25 gaps. The fine filtration region 920 is also arranged downstream of the coarse filtration section 910, near to the outlet 903. Notably, in this configuration, there are no by-pass gaps in the fine-filter region, as the pillars line the fluid chamber 901 from wall to wall. For the comparison, a microfiltration unit according to the invention with the layout shown in FIG. 2B was fabricated, using a configuration of 0.8 μm^{f}: 1.8 μm^{c}: 3.8 μm^{c} (‘by-pass filter’, Chip 2). Both chips had a depth of 30 μm. Filtered PBS buffer was pumped through each chip at 5 and 1 μL/min, respectively. As shown in FIG. 13B, the pressure drop over the by-pass filter increased initially and stabilized at 29.4 kPa and 2.1 kPa within 25 min as indicated by lines 951 and 952, respectively for each flow rate. In contrast, the pressure drop over the zig-zag filter increased continuously and reached up to 700 kPa within 60 min at 5 μL/min, while at 1 μL/min, it saturated at 85.3 kPa at 54 min, as indicated by lines 953 and 954.

A further experiment was carried out by evaluating flow characteristics of the by-pass filter after injecting filtered plain PBS solution containing polystyrene beads. 4 identical by-pass filters with a filter configuration of 0.2 μm^{f}: 1.2 μm^{c}: 3.2 μm^{c} were fabricated. A control experiment was set up in which pure water was passed into Chip 1 and Chip 2 and the pressure drop was monitored over a period of time. 2 identical chips were used top observe for any possible random errors. The pressure drop for Chip 1 and Chip 2 is depicted by line 1011 and 1012, respectively. The readings were used as a control/baseline for comparison against a second experiment in which water containing glass beads were introduced into the chips.

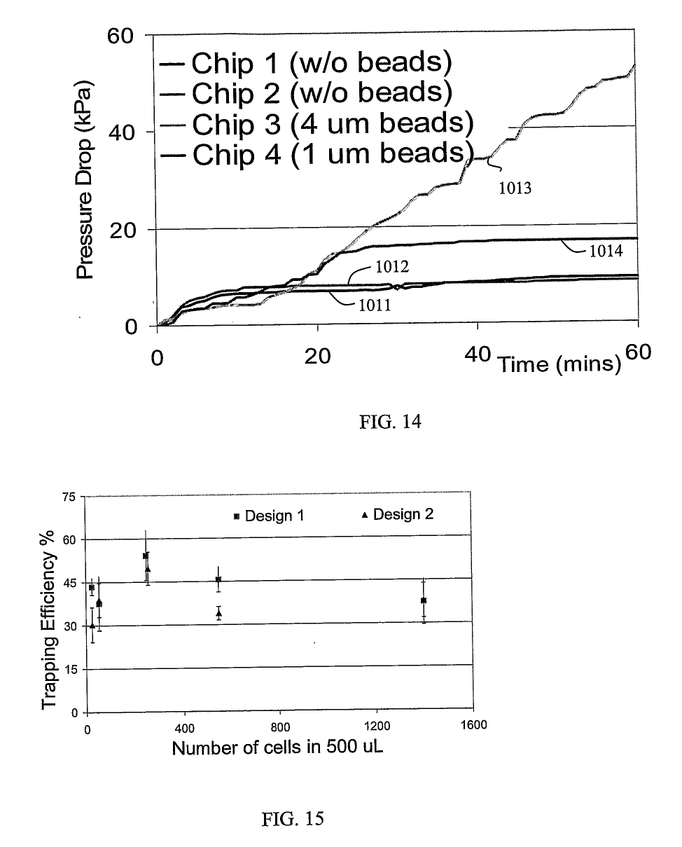

In the second experiment, pure water containing 1 μm polystyrene beads at 500 beads/μL and pure water containing 4 μm polystyrene beads at 150 beads/μL, respectively, were introduced into Chip 3 and Chip 4 at a flow rate of 15 μL/min. With the 4 μm beads, as shown by line 1013 in FIG. 14, the pressure drop climbed as time progressed. This is because the inter-pillar gaps of both fine and coarse filtration sections became increasingly clogged with particles, thus decreasing the available cross-sectional area for the fluid to pass. As the size of the beads were larger than the coarse filter gap sizes of 3.2 μm in the coarse filtration section, the beads could not escape even through the coarse filtration section either. Pressure drop thus kept increasing with 4 μm beads and the microfiltration unit became blocked after about 2 hours of continuous injection. With the 1 μm beads in Chip 4, initially the pressure drop increased as the glass beads started occupying the inter-pillar gaps in the fine filtration section with 0.2 μm filter gap, and the beads escaping the 1.2 μm and 3.2 μm coarse filter section. However, upon reaching its filtration capacity (i.e. once the fine filtration section is fully occupied), the pressure drop saturated at 16-17 kPa within 30 min, as depicted by line 1014 in FIG. 14. It is suggested that once the filtration capacity is reached, the fluid stops flowing through the fine filtration sections, and instead, adopts a steady-state serpentine flowpath by flowing through the coarse filtration sections.

In summary, the present tests showed that the filter was not blocked by the excess micro-particles that had sizes smaller than the by-pass coarse filtration sections. Through the testing of pressure drop over the filter chips, it was also shown that (a) the pressure drop has been greatly reduced up to 700 kPa for the diamond pillar filter to 29.4 kPa for the rain drop pillar by-pass filter at 5 μL/min, and (b) the by-pass filter is less clog-sensitive and has high liquid handling capacity, as it is not blocked by the micro-particles that cannot pass through the fine filter gaps.

### ii) Trapping Efficiency Test

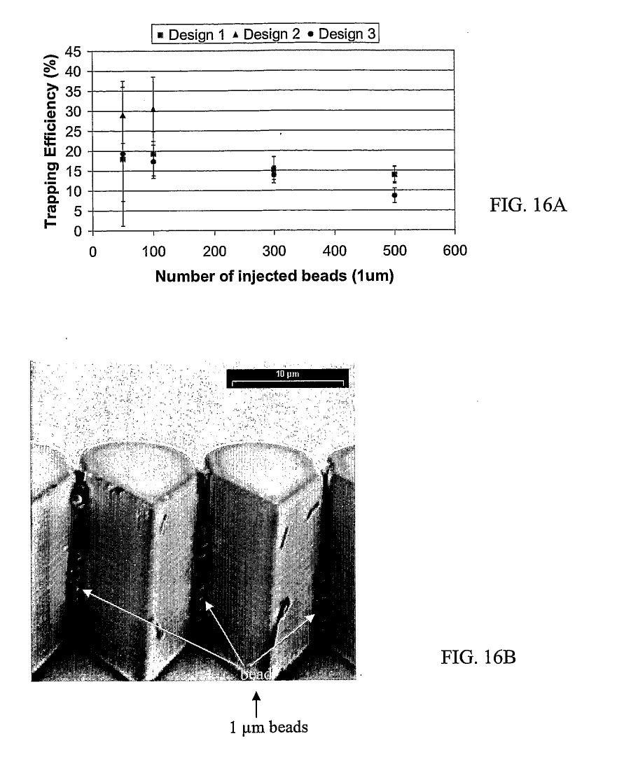

Trapping efficiencies of the rain drop pillar by-pass filter was evaluated with protozoa cells —C. parvum and G. lamblia, 1 μm beads and E. coli. Design 1, 2, 3 all of which have a configuration of 4 μm^{c}: 2 μm^{c}: 1 μm^{f}, respectively having proportions of 150/300/4050, 300/600/3600 and 500/1000/3000 were used for the evaluation. Trapping efficiency of by-pass filter with 1 μm pillar gap and 30 μm chamber depth was firstly evaluated with protozoa cells, C. parvum and G. lamblia. Sample solution was injected into the chip at 20 μL/min followed by flush of fluorescence labeled antibody solution for 10 min at 50 μL/min. After washing with PBS buffer for 2 min, the cells were fluorescently labelled inside the chip and ready for microscopic observation. FIG. 15 shows the trapping efficiencies obtained at various C. parvum cell numbers in 500 μL PBS solution using a filter chip of Design 2. Highest trapping efficiency of 49.6±5.7% were achieved at a concentration of 257 cells in 500 μL. 8 cells were observed in front of the filter out of 25 cells injected, with a trapping efficiency of ˜30%.

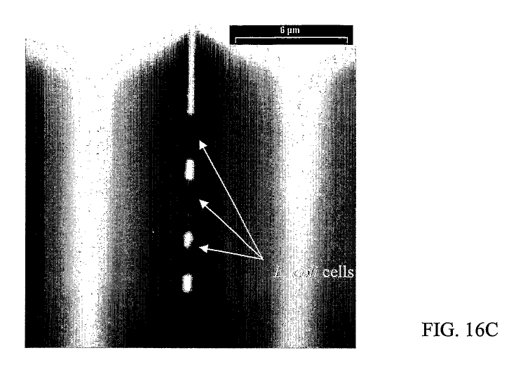

Trapping efficiency of by-pass filter with 0.2 to 0.3 μm pillar gap in the fine filtration section and 13 μm chamber depth was then evaluated with 1 μm beads. FIG. 16A shows the trapping efficiencies for the 3 designs. Surprisingly, Design 2 gave the highest trapping efficiencies probably due to the balances between ratio of length and the ratio of pressure drops between fine filter and by-pass filter. The relatively big standard deviation was caused by the difficulty of counting beads inside the filter chip. The overlaid beads FIG. 16B before the pillar units were counted as one bead as they appear as one single bright spot from the top-view under a microscope. The actual trapping efficiencies may be much higher than those showed in FIG. 16A if an actual count was made to determine the actual number of trapped particles in each filter gap.

Trapping efficiency of by-pass filter with 0.1 μm pillar gap and 13 μm chamber depth was further evaluated with E. coli. As counting of E. coli cells inside the chip is impossible due to the limited magnification using a fluorescence microscope and the highly overlaid cells before the filter (FIG. 16C), calculation of trapping efficiencies was not feasible. Detection limit was observed to be about 26,000 cells with DAPI staining, which gave poor and quickly photo-bleached fluorescent signal. Testing of bacteria cells of about 1 μm size could be further improved by using brighter fluorescent labelling reagent or other means.

Based on the above test results, the microfiltration unit according to the invention can be used for the detection of protozoa cells or bacterium in actual samples (e.g. water samples from natural sources like reservoir, etc.). With further integration of other purification unit operation modules (e.g. immuno-magnetic separation), the present microfiltration unit can form an integral unit in a complete microfluidic system for a wide variety of applications.

1. A microfluidic filtration unit for trapping particles of a predetermined nominal size present in a fluid, comprising:
a fluid chamber connected to an inlet for introducing the fluid to be filtered and an outlet for discharging filtered fluid,
a filtration barrier arranged within the fluid chamber, said filtration barrier comprising a plurality of pillars arranged substantially perpendicular to the path of fluid flow when fluid is introduced into the fluid chamber, said pillars being aligned to form at least one row extending across said path of fluid flow,
wherein each of said at least one row of pillars in the filtration barrier comprises at least one fine filtration section comprising a group of pillars that are spaced apart to prevent particles from moving between adjacent pillars, and
at least one coarse filtration section comprising a group of pillars that are spaced apart to permit the movement of particles between adjacent pillars.

2. The microfluidic filtration unit of claim 1, wherein the adjacent pillars of the at least one fine filtration section are spaced apart from each other at a distance smaller than the predetermined nominal size of the particles to be filtered from the fluid.

3. The microfluidic filtration unit of claim 2, wherein the distance between adjacent pillars in the fine filtration section is between about 0.1 μm to about 1.0 μm.

4. The microfluidic filtration unit of claim 1, wherein the adjacent pillars in the at least one coarse filtration section are spaced apart from each other at a distance larger than the predetermined nominal size of the particles to be filtered from the fluid.

5. The microfluidic filtration unit of claim 4, wherein the distance between adjacent pillars in the coarse filtration section is between about 2 μm to about 4 μm.

6. The microfluidic filtration unit of claim 1, wherein the ratio of the total cross sectional area of the space between adjacent pillars in the fine filtration section to the total cross sectional area of the space between adjacent pillars in the coarse filtration section is between about 0.3 to about 1.7.

7. The microfluidic filtration unit of claim 1, wherein the filtration barrier comprises at least two rows of pillars comprising an upstream row and downstream row.

8. The microfluidic filtration unit of claim 7, wherein the fine filtration section and the coarse filtration section are each arranged in an alternating (staggered) manner from one row to an adjacent row, thereby establishing a meandering filtration path in the filtration barrier.

9. The microfluidic filtration unit of claim 7, wherein the position of the fine filtration section(s) in the downstream row corresponds to the position of the coarse filtration section(s) in the upstream row.

10. The microfluidic filtration unit of claim 8, wherein the cross-sectional area of each fine filtration section(s) in the downstream row of pillars is larger than the cross sectional area of the coarse filtration section(s) to which it corresponds in the upstream row of pillars.

11. The microfluidic filtration unit of claim 7, wherein the upstream row of pillars comprises two coarse filtration sections, each arranged at one end of the row, and a fine filtration section arranged in the middle of the row.

12. The microfluidic filtration unit of claim 11, wherein the distance between adjacent pillars in each of the two coarse filtration sections increases towards the end of the row.

13. The microfluidic filtration unit of claim 12, wherein the coarse filtration section comprises a first group of pillars wherein each pillar is spaced apart from each other at a distance of about 2 μm, and a second group of pillars wherein each pillar is spaced apart from each other at a distance of about 4 μm.

14. The microfluidic filtration unit of claim 1, wherein the pillars have a cross-sectional shape selected from a circular shape, an elliptical shape, a polygonal shape, and a raindrop shape.

15. The microfluidic filtration unit of claim 1, wherein the pillars have a raindrop cross-sectional shape comprising
a pointed front section arranged to be incident to the flow of fluid,
an elongated middle section, and
a substantially rounded rear section.

16. The microfluidic filtration unit of claim 1, wherein the pillars are formed via deep reactive ion etching (RIE) and conformal deposition.

17. The microfluidic filtration unit of claim 1, wherein the filtration barrier is located in a reaction zone in the fluid chamber, said reaction zone comprising an enlarged cross-sectional area relative to the cross-sectional area of the inlet.

18. The microfluidic filtration unit of claim 1, further comprising a large particle filter located proximate to the inlet.

19. The microfluidic filtration unit of claim 1, further comprising a housing within which the fluid chamber is arranged.

20. The microfluidic filtration unit of claim 1, wherein the housing comprises a planar base substrate, an intermediate planar member attached to the planar base substrate, said intermediate planar member having a hollow central section surrounded by side walls defining the fluid chamber, and a transparent cover attached to the intermediate planar member.

21. The microfluidic filtration unit of claim 20, wherein the side walls are tapered towards one or more fine filtration sections in the first row of pillars in the filtration barrier.

22. The microfluidic filtration unit of claim 20, wherein the base substrate and intermediate planar member are integrally formed.

23. The microfluidic filtration unit of claim 20, wherein the transparent cover is removable.

24. The microfluidic filtration unit of claim 1, wherein the microfluidic filtration unit is operably connected to one or more microfluidic unit operations modules for processing biological material.

25. The microfluidic filtration unit of claim 24, wherein said microfluidic unit operations modules is selected from the group consisting of micromixers, micropumps, and microreactors.

26.-30. (canceled)

31. A microfluidic filtration device for trapping particles of a predetermined nominal size present in a fluid, comprising:
a housing having defined therein a fluid chamber, an inlet defined in said housing for introducing the fluid to be filtered, and an outlet defined in said housing for discharging filtered fluid, and
a filtration barrier arranged within the fluid chamber, said filtration barrier comprising a plurality of pillars arranged substantially perpendicular to the path of fluid flow when fluid is introduced into the fluid chamber, said pillars being aligned to form at least one row extending across said path of fluid flow,
wherein each of said at least one row of pillars in the filtration barrier comprises at least one fine filtration section comprising a group of pillars that are spaced apart to prevent particles to be filtered from the fluid from moving between adjacent pillars, and
at least one coarse filtration section comprising a group of pillars that are spaced apart to permit the movement of particles between adjacent pillars.

32. A microfluidic filtration unit for trapping particles of a predetermined nominal size present in a fluid, comprising:
a fluid chamber connected to an inlet for introducing the fluid to be filtered and an outlet for discharging filtered fluid,
a filtration barrier arranged within the fluid chamber, said filtration barrier comprising a plurality of pillars arranged substantially perpendicular to the path of fluid flow when fluid is introduced into the fluid chamber, said pillars being aligned to form at least one row extending across said path of fluid flow,
wherein each of said at least one row of pillars in the filtration barrier comprises at least one fine filtration section comprising a group of pillars that are spaced apart to prevent the particles to be filtered from the fluid from moving between adjacent pillars, and
at least one by-pass section comprising a gap which permits the movement of the particles.
